(19) United States
(12) Patent Application Publication
(10) Pub. No.: US 2013/0026569 A1
(43) Pub. Date: Jan. 31, 2013

(54) METHODS AND APPARATUS RELATED TO HOT CARRIER INJECTION RELIABILITY IMPROVEMENT

(71) Applicant: Jifa Hao, Scarborough, ME (US)

(72) Inventor: Jifa Hao, Scarborough, ME (US)

(21) Appl. No.: 13/192,208

(22) Filed: Jul. 27, 2011

(51) Int. Cl. H01L 29/78; H01L 21/336

(52) U.S. Cl. 257/344; 438/302; 257/E29.266; 257/E21.437

(57) ABSTRACT

In one general aspect, an apparatus can include a substrate, a gate electrode, and a gate dielectric having at least a portion disposed between the gate electrode and the substrate. The apparatus can include a heavily doped drain region disposed within the substrate, and a lightly doped drain region within the substrate and in contact with the heavily doped drain region. The apparatus can also include a medium doped drain region disposed within the lightly doped drain region and having a dopant concentration between a dopant concentration of the heavily doped drain region and a dopant concentration of the lightly doped drain region.

### TECHNICAL FIELD

This description relates to hot carrier injection within a metal-oxide-semiconductor field effect transistor (MOSFET) device.

### BACKGROUND

Hot carrier injection (HCI) can be caused by an electron (or hole) gaining sufficient kinetic energy to overcome a potential barrier necessary to break an interface state and become trapped at, or around, for example, an interface between a gate dielectric and/or a surface of a substrate of a metal-oxide-semiconductor field effect transistor (MOSFET) device. Hot carrier injection (and trapping) in the MOSFET device can cause shifts (e.g., degradation in) linear region current (e.g., I_{DLIN}), saturation current (e.g., I_{DSAT}), transconductance (G_{M}), and/or threshold voltage (V_{TH}) of the MOSFET device, which can result in a reduced reliability (or life) of the MOSFET device. Various known techniques have been implemented to reduce hot carrier injection within MOSFET devices such as reducing a maximum electrical field “Emax” of the MOSFET devices or pushing an impact ionization region far below the silicon surface of the MOSFET devices. Although these techniques can reduce hot carrier injection, these known methods can result in MOSFET device performance that is undesirable such as relatively slow switching characteristics, and so forth. Thus, there is a need for apparatus and methods to address the shortfalls of present technology and to provide other new and innovative features.

### SUMMARY

In one general aspect, an apparatus can include a substrate, a gate electrode, and a gate dielectric having at least a portion disposed between the gate electrode and the substrate. The apparatus can include a heavily doped drain region disposed within the substrate, and a lightly doped drain region within the substrate and in contact with the heavily doped drain region. The apparatus can also include a medium doped drain region disposed within the lightly doped drain region and having a dopant concentration between a dopant concentration of the heavily doped drain region and a dopant concentration of the lightly doped drain region.

In another general aspect, an apparatus can include a substrate, a gate electrode, and a gate dielectric having at least a first portion disposed between the gate electrode and the substrate. The apparatus can include a spacer disposed over a second portion of the gate dielectric and in contact with the gate electrode, and a first doped drain region at an interface between gate dielectric and the substrate. The apparatus can also include a second doped drain region at an interface between the second portion of the gate dielectric and the substrate where the second doped drain region has a dopant concentration configured to offset electric charge associated with a plurality of electrons trapped at the interface between the second portion of the gate dielectric and the substrate in response to hot carrier injection. The dopant concentration of the second doped drain region can be greater than a dopant concentration of the first doped drain region.

In yet another general aspect, a method can include forming a gate dielectric on a substrate, and forming a gate electrode over a portion of the gate dielectric. The method can include implanting a dopant into a region of the substrate until the region has a first dopant concentration, and increasing a concentration of a portion of the region. The method can also include forming a drain region having a second dopant concentration greater than the first dopant concentration.

The details of one or more implementations are set forth in the accompanying drawings and the description below. Other features will be apparent from the description and drawings, and from the claims.

### BRIEF DESCRIPTION OF THE DRAWINGS

FIG. 1A is a diagram that illustrates a metal-oxide semi-conductor field effect transistor (MOSFET) device, according to an embodiment.

FIG. 1B is a diagram that illustrates a zoomed in view of a portion of the MOSFET device shown in FIG. 1A.

FIG. 1C is a diagram that illustrates a top view of the doped drain regions shown in FIG. 1B.

FIGS. 2A through 2D are diagrams that illustrate a method for producing a medium doped drain region in a MOSFET device, according to an embodiment.

FIGS. 3A through 3C are diagrams that illustrate another method for producing a medium doped drain region in a MOSFET device, according to an embodiment.

FIG. 4 is a flowchart that illustrates a method for forming a medium doped drain region, according to an embodiment.

### DETAILED DESCRIPTION

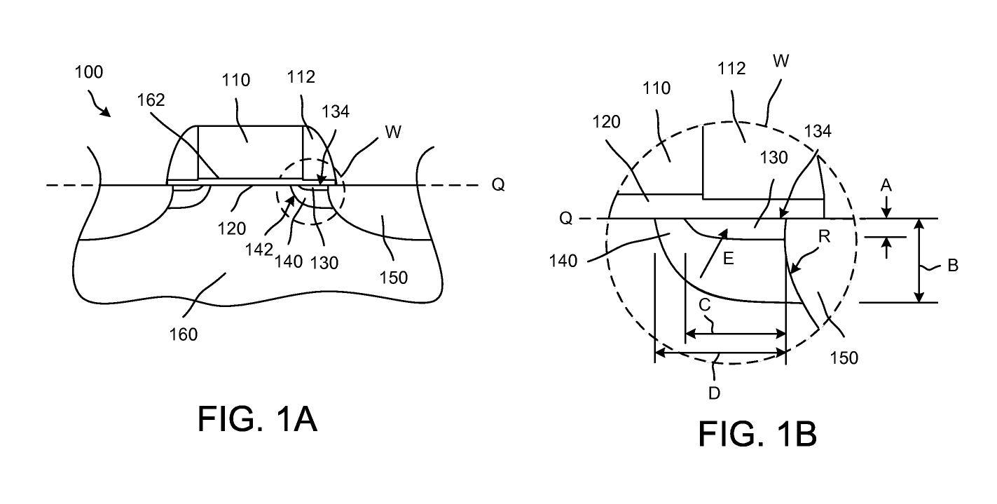

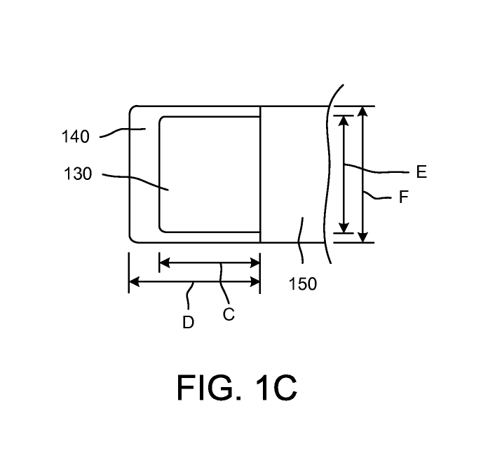

FIG. 1A is a diagram that illustrates a metal-oxide-semiconductor field effect transistor (MOSFET) device 100, according to an embodiment. Because the MOSFET device 100 has mirrored features, the MOSFET device 100 will generally be discussed in terms of a single side.

The MOSFET device 100 can include a substrate portion 160 (or a portion thereof), and a gate dielectric 120 (e.g., a gate oxide) disposed between a gate electrode 110 and the substrate portion 160. The substrate portion 160 shown in FIG. 1A can be, for example, doped with a P-type dopant and can be a P-well region of the MOSFET device 100. The gate dielectric 120 is disposed on (e.g. along) a surface 162 of the substrate portion 160, and the gate electrode 110 is disposed above the gate dielectric 120. The surface 162 of the substrate portion 160 is aligned along a plane Q. The gate electrode 110 is described as being disposed above the gate dielectric 120 because the gate electrode 110 is oriented vertically above the gate dielectric 120 along a line orthogonal to (substantially orthogonal to) the plane Q. In some embodiments, the gate electrode 110 can be made of, for example, a polysilicon material.

As shown in FIG. 1A, a spacer 112 is disposed lateral to the gate electrode 110. The spacer 112 is described as being lateral to the gate electrode 110 because the spacer 112 is disposed to the left (or right) of the gate electrode 110 (along the plane Q in a horizontal direction) when the substrate 160 is oriented as shown in FIG. 1A. In this embodiment, the spacer 112 is in contact with the gate electrode 110. In some embodiments, the spacer 112 can be made of, for example, a tetraethyl orthosilicate (TEOS) material.

In some embodiments, the substrate portion 160 can be, or can be associated with, an epitaxial layer (e.g., an N-type epitaxial layer). In some embodiments, the MOSFET device 100 shown in FIG. 1A can be part of a complementary MOS (CMOS) device, a device that includes bipolar junction transistors integrated with CMOS devices (BiCMOS), and/or so forth.

The MOSFET device 100 includes a medium doped drain region 130 (or layer) formed after, or while, a lightly doped drain region 140 (or layer) is formed. As shown in FIG. 1A, the medium doped drain region 130 is in contact with the lightly doped drain region 140 and is in contact with a heavily doped drain region 150. In some embodiments, the medium doped drain region 130 can be referred to as being disposed within the lightly doped regain region 140. Although discussed herein as drain regions, the drain regions can function as source regions of the MOSFET device 100 and can be referred to as such. In some embodiments, the lightly doped drain region 140, the medium doped drain region 130, and a heavily doped drain region 150 can collectively be referred to as a drain (or source) and can each be referred to as a portion of the drain (or source).

The medium doped drain region 130 has a dopant concentration (and implant dose) that is higher than a dopant concentration (and implant dose) of the lightly doped drain region 140. The dopant concentration can be achieved using an implant dose that is approximately proportional to the dopant concentration. Accordingly, discussion herein related to dopant concentration can be interchangeable with implant dose. In some embodiments, the medium doped drain region 130 can function as, or can be, a relatively high concentration portion of the lightly doped drain region 140. In some embodiments, the medium doped drain region 130 can function as, or can be, a relatively high concentration surface portion of the lightly doped drain region 140. In some embodiments, the medium doped drain region 130, the lightly doped drain region 140, and the heavily doped drain region 150 can each be doped with an N-type dopant (e.g., phosphorus, boron, arsenic). In some embodiments, a dopant used in the medium doped drain region 130 can be different than a dopant used in the heavily doped drain region and/or the lightly doped drain region 140. As shown in FIG. 1A, the medium doped drain region 130 (or a portion thereof) is at the surface 162 of the substrate 160.

The medium doped drain region 130 is configured to reduce (or screen) the effects of trapped charges related to hot carrier injection. Hot carrier injection (HCI) can be caused by an electron (or hole) gaining sufficient kinetic energy to overcome a potential barrier necessary to break an interface state and become trapped at, or around, for example, an interface 134 between the gate dielectric 120 (e.g., a portion of the gate dielectric 120 below the spacer 112, a portion of the gate dielectric 120 below a portion of the gate electrode 110) and/or the surface 162 of the substrate 160. The trapped charges, in this embodiment, can be electrons, which can be referred to as hot electrons (hot-e⁻) or as hot carrier electrons. In some embodiments, the hot electrons can be generated at, or around, an interface 142 (e.g., a PN junction) defined by the lightly doped drain region 140 and the substrate 160. Specifically, an electric field associated with a depletion region at the interface 142 can cause the generation of the hot electrons that can be injected into and trapped at the interface 134.

The relatively high concentration (e.g., high surface concentration) of the medium doped drain region 130 can be configured to offset (or compensate for) electric charge associated with electrons (e.g., hot electrons) trapped at, or around, the interface 134 between the spacer 112 and the surface 162 of the substrate 160. The electrons can be generated and can become trapped due to hot carrier injection. The relatively high concentration (e.g., high surface concentration) of dopants in the medium doped drain region 130 can have an electric charge (e.g., an electric charge density) configured to offset electric charge (e.g., an electric charge density) associated with trapped electrons at a higher rate than the relatively low concentration of the lightly doped drain region 140 (without the medium doped drain region 130). In other words, the doping (or number of dopant molecules) of the medium doped drain region 130 can have an electric charge that offsets an electric charge associated with hot carrier electrons (or an increasing electric charge as hot carrier electrons are trapped). Said differently, the dopant concentration (or number of dopant molecules or implant dose) of the medium doped drain region 130 can have an electric charge that compensates for electric charges associated with hot carrier electrons as the hot carrier electrons are trapped so that an overall charge in the region changes at a rate that is slower than without the dopant concentration (or number of dopant molecules or implant dose) of the medium doped drain region 130.

Hot electrons, when trapped at an interface of a MOSFET device (such as MOSFET device 100 without the medium doped drain region 130), can alter the MOSFET device in an undesirable fashion. Specifically, a long-term reliability of the MOSFET device can be decreased by the hot electrons. In some embodiments, the switching characteristics of the MOSFET device can be affected in an adverse fashion. Hot carrier injection (and trapping) in the interface (and/or the gate dielectric) at, or near, the lightly doped drain region can cause shifts (e.g., degradation in) linear region current (e.g., I_{DLIN}), saturation current (e.g., I_{DSAT}), transconductance (G_{M}), and/or threshold voltage (V_{TH}) in the MOSFET device, which can result in a reduced reliability (or life) of the MOSFET device. In some embodiments, the hot carrier injection can be particularly problematic for the MOSFET device when the MOSFET device is a submicron MOSFET device with a gate length less than 1 micron (e.g., a MOSFET device with a gate length less than 100 nm, a MOSFET device with a gate length less than 50 nm).

For example, with the hot carrier compensation provided by the medium doped drain region 130, a reliability (e.g., a threshold reliability) of the MOSFET device 100 may be higher than the reliability of a MOSFET device without the hot carrier compensation provided by a medium doped drain region (e.g., medium doped drain region 130). In other words, a reliability of the MOSFET device 100, if the medium doped drain region 130 were not included within the lightly doped drain region 140, may be lower than the reliability of the MOSFET device 100 with the medium doped drain region 130 included in (e.g., disposed within) the lightly doped drain region 140. In some embodiments, the inclusion of the medium doped drain region 130 (compared with the omission of the medium doped drain region 130) within the lightly doped drain region 140 can result in an increase in reliability (e.g., direct current (DC) reliability) of more than 10 times (e.g., 100 times, 1000 times). In some embodiments, the inclusion of the medium doped drain region 130 (compared with the omission of the medium doped drain region 130) within the lightly doped drain region 140 can reduce shifts (e.g., percentage shifts in, rate of shifting) in linear region current (e.g., I_{DLIN}), saturation current (e.g., I_{DSAT}), transconductance (G_{M}), and/or threshold voltage (V_{TH}) in the MOSFET device 100 by more than 1.5 times (e.g., 2 times, 3 times).

The doped drain regions 130, 140, and 150 are formed so that a volume of the lightly doped drain region 140 is greater than a volume of the medium doped drain region 130. In some embodiments, the volume of lightly doped drain region 140 can be approximately the same as, or less than, the volume of the medium doped drain region 130. Both the lightly doped drain region 140 and the medium doped drain region 130 each have volumes (and a combined volume in some instances) that is smaller than a volume of the heavily doped drain region 150. In some embodiments, the medium doped drain region 140 can be formed within a relatively small portion (or volume) of the lightly doped drain region 140.

FIG. 1B is a diagram that illustrates a zoomed in view of a portion W of the MOSFET device 100 shown in FIG. 1A. As shown in FIG. 1B, a thickness A (e.g., an average thickness) of the medium doped drain region 130 is less than a thickness B (e.g., an average thickness) of the lightly doped drain region 140. In some embodiments, the thickness A of the medium doped drain region 130 can be approximately between 100 Å to 1000 Å (e.g., 200 Å, 500 Å). In some embodiments, the thickness A of the medium doped drain region 130 can be less than 100 Å (e.g., 50 Å), or greater than 1000 Å. In some embodiments, a ratio of the thickness A of the medium doped drain region 130 to the thickness B of the lightly doped drain region 140 can be approximately between 1:1.5 to 1:20. In some embodiments, the ratio of the thickness A to the thickness B can be less than 1:1.5, or greater than 1:20.

As shown in FIG. 1B, a length C (e.g., an average length) of the medium doped drain region 130 is less than a length D (e.g., an average length) of the lightly doped drain region 140. In some embodiments, the length C of the medium doped drain region 130 can be approximately between 500 Å to 5000 Å (e.g., 2000 Å, 4000 Å). In some embodiments, the length C of the medium doped drain region 130 can be less than 500 Å (e.g., 100 Å), or greater than 1000 Å (e.g., 2 microns). In some embodiments, the length C of the medium doped drain region 130 can be approximately between 50% to 95% of the length D of the lightly doped drain region 140. In some embodiments, the length C can be more than 95% of the length D (e.g., 100%, 120%), or can be less than 50% of the length D (e.g., 25%).

As shown in FIG. 1B, at least a portion (e.g., a footprint) of the spacer 112 is disposed above (vertically above, projected onto from above) at least a portion of the medium doped drain region 130, and at least a portion of the heavily doped drain region 150. As shown in FIG. 1B, at least a portion (e.g., a footprint) of the gate electrode 110 is disposed above (vertically above, projected onto from above) at least a portion of the medium doped drain region 130, and at least a portion of the lightly doped drain region 140.

In this embodiment, the length C and the length D are measured approximately from an interface between the medium doped drain region 130 and the heavily doped drain region 150. In some embodiments, the medium doped drain region 130 and the lightly doped drain region 140 can be characterized as collectively defining an interface R with the heavily doped drain region 150. Specifically, the medium doped drain region 130 defines at least a first portion of the interface R and the lightly doped drain region 140 defines at least a second portion of the interface R. The first portion of the interface R is disposed between the gate dielectric 120 and the second portion of the interface R.

In some embodiments, the medium doped drain region 130 can have a dopant concentration (or implant dose) (e.g., an N-type dopant concentration) that is approximately 1.5 to 4 times higher (e.g., 2 times, 3 times) than a dopant concentration (or implant dose) of the lightly doped drain region 140. In some embodiments, the dopant concentration (or implant dose) of the medium doped drain region 130 can be less than 1.5 times (e.g., 1.2 times) the dopant concentration (or implant dose) of the lightly doped drain region 140, or can be greater than 4 times (e.g., 5 times) the dopant concentration (or implant dose) of the lightly doped drain region 140.

As a specific example, the dopant concentration of the medium doped drain region 130 can be achieved using an implant dose of approximately between 3e 13 cm⁻² to 4.5e13 cm⁻² while the dopant concentration of the lightly doped drain region 140 can be achieved using an implant dose of approximately between 2e13 cm⁻² to 2.7e13 cm⁻². In some embodiments, the dopant concentration of the medium doped drain region 130 can be achieved using an implant dose of less than 3e13 cm⁻² or greater than 4.5e13 cm⁻².

In some embodiments, the medium doped drain region 130 can have a dopant concentration (e.g., an N-type dopant concentration) that is approximately 2 to 4 times less (e.g., 2 times, 3 times) than a dopant concentration of the heavily doped drain region 150. In some embodiments, the dopant concentration of the medium doped drain region 130 can be less than 2 times (e.g., 1.2 times) less than the dopant concentration of the heavily doped drain region 150, or can be more than 4 times (e.g., 5 times) less than the dopant concentration of the heavily doped drain region 150. In some embodiments, the medium doped drain region 130 can have a dopant concentration that is greater than a dopant concentration of the heavily doped drain region 150.

In some embodiments, the dopant concentration of the medium doped drain region 130 and/or the lightly doped drain region 140 can decrease approximately along direction E. Accordingly, a dopant concentration of medium doped drain region 130 at approximately an interface between the medium doped drain region 130 and the lightly doped drain region 140 can be less than a dopant concentration of the medium doped drain region 130 at approximately the interface 134.

FIG. 1C is a diagram that illustrates a top view of the doped drain regions 130, 140, and 150 shown in FIG. 1B. This top view is at the surface 162 (along plane Q) of the substrate 160. As shown in FIG. 1C, the medium doped drain region 130 (or a perimeter thereof) is entirely enclosed within the lightly doped drain region 140 (or a perimeter thereof). As shown in FIG. 1C, the lightly doped drain region 140 has a width E that is greater than a width F of the medium doped drain region 130. In some embodiments, the lightly doped drain region 140 can have a width E that is the same as or smaller than a width F of the medium doped drain region 130.

Although not shown in FIG. 1C, in some embodiments, the spacer 112 (if projected onto the doped drain regions 130, 140, and 150 shown in FIG. 1B from above) can have a perimeter that is disposed outside of at least a portion of the perimeter of the medium doped drain region 130 and/or the lightly doped drain region 140. Although not shown in FIG. 1C, in some embodiments, the gate electrode 110 (if projected onto the doped drain regions 130, 140, and 150 shown in FIG. 1B from above) can have a portion that is disposed on at least a portion of the perimeter of the medium doped drain region 130 and/or the lightly doped drain region 140.

In some embodiments, formation of the medium doped drain region 130 within the lightly doped drain region 140 can result in shifting of one or more electrical parameters of the MOSFET device 100 compared with a MOSFET device (not shown) that does not include a medium doped drain region (with other features, aspect ratios, etc. being the same).

In some embodiments, the MOSFET device 100 and other MOSFET devices (not shown) similar to MOSFET device 100 can be included in one or more discrete components. In such embodiments, the MOSFET device 100 and the other MOSFET devices (not shown) can collectively function as a single MOSFET device.

In some embodiments, the MOSFET device 100 can be included in (e.g., integrated into), for example, a computing device (not shown). In some embodiments, the computing device can be, for example, a computer, a personal digital assistant (PDA), a memory component (e.g., a hard disk drive), a host computer, an electronic measurement device, a data analysis device, a cell phone, a power supply, an automotive electronic circuit, an electronic device, and/or so forth. In some embodiments, the MOSFET device 100 can be used in a variety of application such as switches that connect power supplies to electronic devices having a load.

The MOSFET device 100 described in connection with FIGS. 1A and 1D can be produced using a variety of techniques. Several methods can be used to produce a surface concentration of the lightly doped drain region 140 (as the medium doped drain region 130) that has a relatively high surface concentration. At least some of methods can include performing a higher implant (e.g., within an implantation process) for the lightly doped drain region 140, multiple implants, using method based on a segregation effect (causing redistribution of dopants within the lightly doped drain region 140), and/or so forth. In some embodiments, a surface concentration of the lightly doped drain region 140 (as the medium doped drain region 130) can have a relatively high surface concentration compared with the bulk concentration of the lightly doped drain region 140 and can be a relatively thin layer. More details related to these methods are described below.

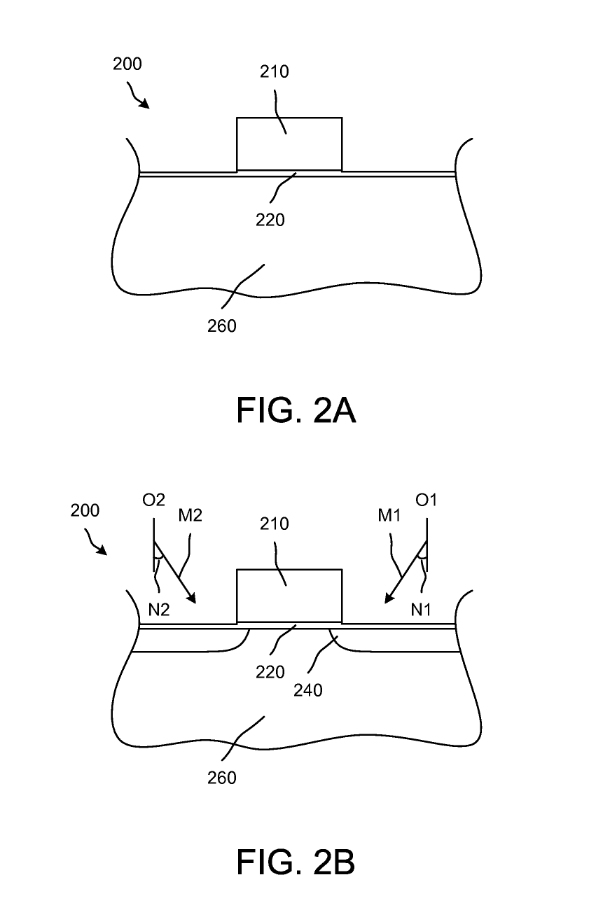

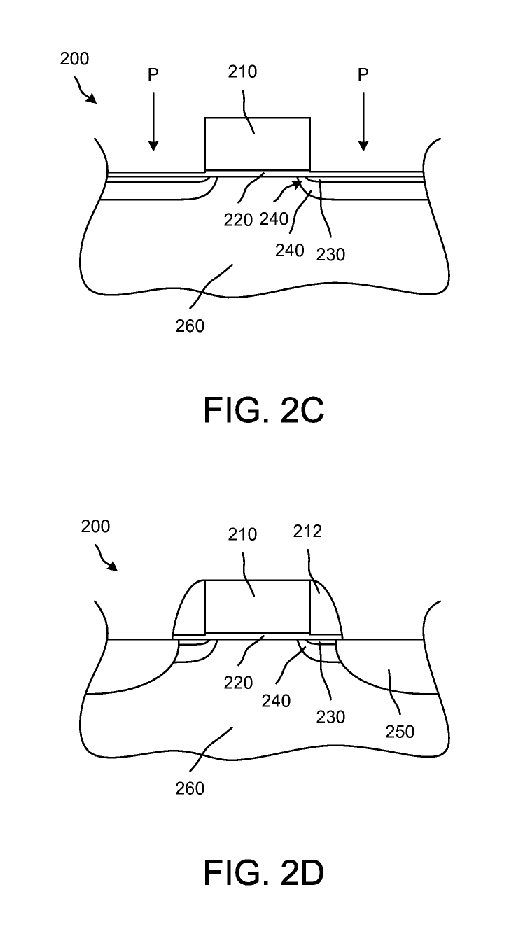

FIGS. 2A through 2D are diagrams that illustrate a method for producing a medium doped drain region in a MOSFET device 200, according to an embodiment. The method (or process) illustrated in FIGS. 2A through 2D can be referred to as a double dopant implantation method (or process).

As shown in FIG. 2A, a gate dielectric 220 is disposed between a substrate portion 260 and a gate electrode 210. FIG. 2A illustrates the MOSFET device 200 after the gate electrode 210 has been etched using a wet etch, a reactive ion etch, and/or so forth. In some embodiments, the gate dielectric 220 can be an oxide that is thermally grown and/or deposited. In some embodiments, the gate electrode 210 can be a polysilicon gate electrode that is deposited on the gate dielectric 220, and etched to form the shape shown in FIG. 2A. As shown in FIG. 2A, the gate dielectric 220 can be etched slightly when the gate electrode 210 is etched.

In some embodiments, the substrate portion 260 shown in FIG. 2A can be, for example, doped with a P-type dopant and can be a P-well region of the MOSFET device 200. In some embodiments, the substrate portion 260 can be, or can be associated with, an epitaxial layer (e.g., an N-type epitaxial layer). In some embodiments, the gate electrode 220 can have thickness of between a few angstroms and several microns (e.g., 50 Å). In some embodiments, the gate electrode 210 can have a thickness of between several nanometers (nm) and several microns (e.g., 200 nm). In some embodiments, the gate electrode 210 can have a width between a few nanometers and several microns (e.g., 50 nm).

In this embodiment, after the gate electrode 210 has been formed, the gate dieletric 220 can be annealed using, for example, an annealing process. In some embodiments, the annealing can be performed to, for example, improve the quality of (e.g., remove dislocations and/or other defects from) the gate dielectric 220. In some embodiments, the annealing process can be a relatively low temperature (or temperature profile) annealing process (e.g., an annealing process performed at temperatures less than 650° C.) or a relatively high temperature (or temperature profile) annealing process (e.g., an annealing process performed at temperatures greater than 650° C.) in, for example, a Nitrogen-based environment (e.g., N₂O). In some embodiments, the annealing can be performed for durations, for example, approximately between 5 to 50 minutes. In some embodiments, the annealing can be performed for durations shorter than 5 minutes or durations greater than 50 minutes.

As shown in FIG. 2B, a lightly doped drain region 240 is formed within the substrate portion 260 by driving (e.g., implanting) a dopant through the gate dielectric 220 and into the substrate portion 260. In some embodiments, the doping of the substrate portion 260 to form the lightly doped drain region 240 can be performed using an implant process (e.g., an ion implantation process using an accelerator). In some embodiments, the lightly doped drain region 240 can be doped with an N-type dopant such as phosphorus, boron, arsenic, and/or so forth. In this embodiment, the formation of the lightly doped drain region 240 is performed after annealing of the gate dielectric 220 is performed.

As illustrated in FIG. 2B, the dopant of the lighted doped drain region 240 is implanted at an angle directed toward the gate electrode 210. Specifically, on the left side of the MOSFET device 200, the dopant is implanted along direction M1 (biased toward the gate electrode 220) at an angle N1 approximately between 25 and 60 degrees (e.g., 45 degrees, 35 degrees) with respect to a vertical axis O1 that is orthogonal to (or substantially orthogonal to) a surface of the substrate portion 260. Similarly, on the right side of the MOSFET device 200, the dopant is implanted along direction M2 (biased toward the gate electrode 220) at an angle N2 approximately between 25 and 60 degrees (e.g., 45 degrees, 35 degrees) with respect to a vertical axis O2 that is orthogonal to (or substantially orthogonal to) a surface of the substrate portion 260.

Because the dopant(s) of the lightly doped drain region 240 is angled in toward the gate electrode 210, the lightly doped drain region 240 can extend under the gate electrode 210 as shown in FIG. 2A. In some embodiments, the dopant of the lightly doped drain region 240 can extend under the gate electrode 210 due to diffusion of the dopant(s) during or after the implantation process.

As shown in FIG. 2C, a medium doped drain region 230 is formed within the substrate portion 260 (e.g., within the lightly doped drain region 240 within the substrate portion 260) by driving (e.g., implanting) a dopant through the gate dielectric 220 and into the substrate portion 260 (e.g., into the lightly doped drain region 240 within the substrate portion 260). In some embodiments, the doping of the substrate portion 260 to form the medium doped drain region 230 can be performed using an implant process (e.g., an ion implantation process using an accelerator). In some embodiments, the medium doped drain region 230 can be doped with an N-type dopant such as phosphorus, boron, arsenic, and/or so forth.

The medium doped drain region 230 can have a dopant concentration (e.g., a dopant level) that is greater than a dopant concentration of the lightly doped drain region 240. In some embodiments, implantation process parameters such as an angle of implantation, a duration of implantation, a dopant type, an acceleration energy, a dopant dose, and/or so forth of the medium doped drain region 230 can be the same as, or different from that of implantation of the lightly doped drain region 240. In some embodiments, the implantation process for the lightly doped drain region 240 can be separate from the implantation process for the medium doped drain region 230. For example, the medium doped drain region 230 can be formed using different implantation process parameters (e.g., acceleration energy, angle, etc.) than implantation process parameters used to form the lightly doped drain region 240.

For example, a duration of an implantation process of the medium doped drain region 230 can be different than a duration of the implantation process of the lightly doped drain region 240. In some embodiments, the duration of the implantation process of the medium doped drain region 230 and/or the lightly doped drain region 240 can be between a few minutes (e.g., 5 minutes, 50 minutes) and one or more hours (e.g., 1.5 hours). The different durations can result in different concentrations of dopant(s) within the medium doped drain region 230 and the lightly doped drain region 240.

As illustrated in FIG. 2C, the dopant of the medium doped drain region 230 is implanted vertically (along direction P) toward the gate electrode 210. In other words, the implantation associated with the medium doped drain region 230 is performed in direction orthogonal to (or substantially orthogonal to) a surface of the substrate portion 260. In some embodiments, the implantation associated with the medium doped drain region 230 can be performed at an angle that is only a few degrees (e.g., ±2 degrees, ±5 degrees, ±7 degrees, ±10 degrees).

Because the dopant(s) of the medium doped drain region 230 is orthogonal to (or substantially orthogonal to) the surface of the substrate, the medium doped drain region 230 does not extend under the gate electrode 210. Instead, on the right side of the MOSFET device 200, a portion 242 of the lightly doped drain region 240 extends beyond the medium doped drain region 230 as shown in FIG. 2A. Because the dopant of the medium doped drain region 230 is implanted vertically (along direction P) toward the gate electrode 210, the implantation associated with the lightly doped drain region 240 extends further under the gate electrode 210 than the medium doped drain region 230. In some embodiments, the dopant of the medium doped drain region 230 can extend under the gate electrode 210 due to diffusion of the dopant(s) during or after the implantation process.

Because the dopant of the medium doped drain region 230 is implanted vertically (along direction P) toward the gate electrode 210, the implantation (e.g., implantation direction) associated with the lightly doped drain region 240 is performed at a different angle than the implantation (e.g., implantation direction) of the medium doped drain region 230. In some embodiments, optionally the implantation associated with the lightly doped drain region 240 can be performed at an angle that is only a few degrees (e.g., ±2 degrees, ±5 degrees, ±7 degrees, ±10 degrees) different than the implantation direction of the medium doped drain region 230. In such embodiments, the medium doped drain region 230 may have a termination point (e.g., a termination point under the gate electrode 210 along a surface of the substrate portion 260) that is closer to a termination point (e.g., a termination point under the gate electrode 210 along a surface of the substrate portion 260) of the lightly doped drain region 240 than if the medium doped drain region 230 and the lightly doped drain region 240 are performed using implantation directions that are different by more than a few degrees.

In some embodiments, a dopant of the medium doped drain region 230 can extend under the gate electrode 210 more than a dopant of the lightly doped drain region 240 due to differences in implantation direction of the medium doped drain region 230 and the lightly doped drain region 240. Specifically, a dopant of the medium doped drain region 230 can be implanted at an angle (with respect to a line orthogonal to a surface of the substrate portion 260) that is greater than an angle of implantation of a dopant of the lightly doped drain region 240.

In some embodiments, the implantation associated with the lightly doped drain region 240 can be performed at an angle (or vertical orientation) that is the same (or substantially the same as) as an angle (or vertical orientation) of the implantation of the medium doped drain region 230. In such embodiments, the medium doped drain region 230 may have a termination point (e.g., a termination point under the gate electrode 210 along a surface of the substrate portion 260) that is the same (or substantially the same as) as a termination point (e.g., a termination point under the gate electrode 210 along a surface of the substrate portion 260) of the lightly doped drain region 240.

In this embodiment, the implantation associated with the lightly doped drain region 240 is performed at an energy (e.g., an acceleration energy) that different from an energy (e.g., an acceleration energy) of the implantation of the medium doped drain region 230. The acceleration energies used for the implantation process can directly affect the drive-in depth (e.g., implantation depth) of the dopants. Accordingly, the medium doped drain region 230 has a depth (from the surface of the substrate portion 260 into the substrate portion 260) that is different from a depth (from the surface of the substrate portion 260 into the substrate portion 260) of the lightly doped drain region 240. Specifically, the medium doped drain region 230 has a depth that is less than (e.g., shallower than) a depth of the lightly doped drain region 240. In some embodiments, the acceleration energy of the implantation process for the lightly doped drain region 240 can be approximately between 40 to 80 keV. In some embodiments, the acceleration energy of the implantation process for the lightly doped drain region 240 can be less than 40 keV or greater than 80 keV. In some embodiments, the acceleration energy of the implantation process for the medium doped drain region 230 can be approximately between 10 to 30 keV. In some embodiments, the acceleration energy of the implantation process for the medium doped drain region 230 can be less than 10 keV or greater than 30 keV.

Although not shown, in some embodiments, the implantation associated with the lightly doped drain region 240 can be performed at an energy (e.g., an acceleration energy) that is the same as an energy (e.g., an acceleration energy) of the implantation of the medium doped drain region 230. In such embodiments, the medium doped drain region 230 can have a depth (from the surface of the substrate portion 260 into the substrate portion 260) that is the same as, or substantially the same as, a depth (from the surface of the substrate portion 260 into the substrate portion 260) of the lightly doped drain region 240.

FIG. 2D is a diagram that illustrates a spacer 212 disposed lateral to the gate electrode 210. The spacer 212 is described as being lateral to the gate electrode 210 because the spacer 212 is disposed to the left (or right) of (in a horizontal direction to) the gate electrode 210 when the substrate portion 260 is oriented as shown in FIG. 2D. In this embodiment, the spacer 212 is in contact with the gate electrode 210. Also, at least a portion of the spacer 212 is disposed lateral to the gate dielectric 220. In some embodiments, the spacer 212 can be made of, for example, a tetraethyl orthosilicate (TEOS) material.

Also, as shown in FIG. 2D, a heavily doped drain region 250 is formed after the spacer 212 has been formed. In some embodiments, the heavily doped drain region 250 can be formed using an implantation process. The heavily doped drain region 250 can have a dopant concentration (e.g., a dopant level) that is greater than a dopant concentration of the medium doped drain region 230 and/or that is greater than a dopant concentration of the lightly doped drain region 240. In some embodiments, an angle of implantation, a duration of implantation, a dopant type, an acceleration energy and/or so forth of the heavily doped drain region 250 can be the same as, or different from that of implantation of the medium doped drain region 230 and/or the lightly doped drain region 240.

In some embodiments, rather than performing two separate implantations to form a medium doped drain region 230 within a lightly doped drain region 240, a single implantation process with, for example, a relatively high dose and energy can be performed. In such embodiments, the entire lightly doped drain region 240 shown in, for example, FIG. 2C can have a dopant concentration that is approximately the same as the dopant concentration of the medium doped drain region 230. In such embodiments, a separate implantation process to form the medium doped drain region 230 may be omitted because the region where the medium doped drain region 230 is formed as shown in, for example, FIG. 2C will already have a relatively high dopant concentration.

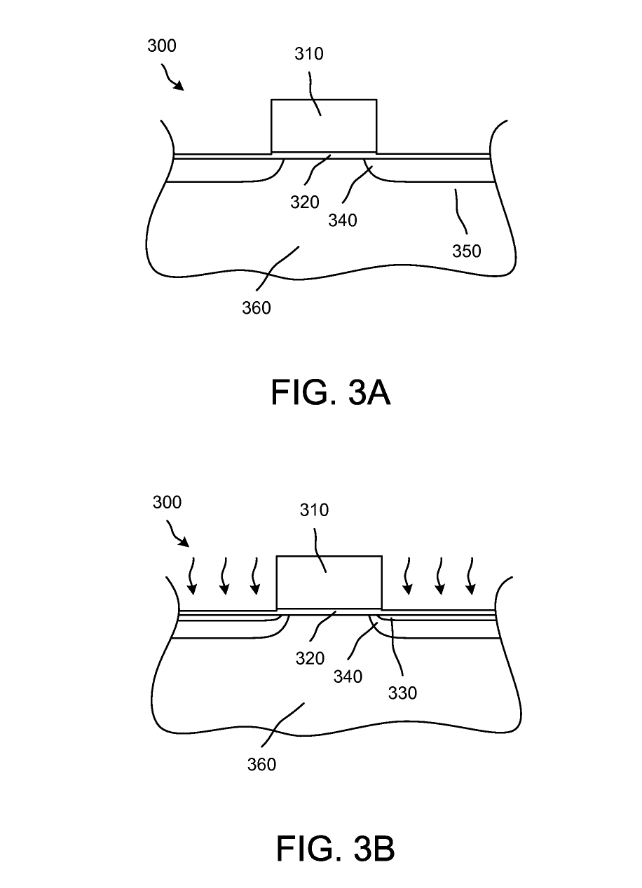

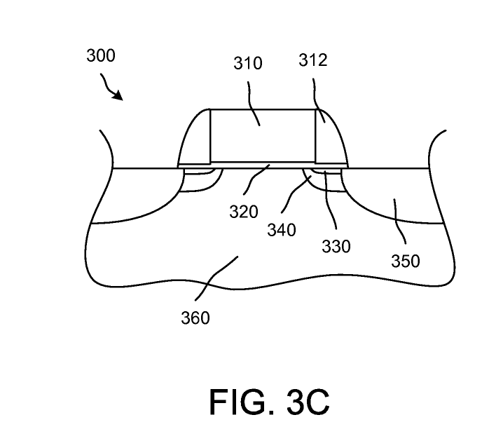

FIGS. 3A through 3C are diagrams that illustrate another method for producing a medium doped drain region in a MOSFET device 300, according to an embodiment. The method (or process) illustrated in FIGS. 3A through 3C can be referred to as a segregation effect method (or process). Many of the processing techniques described above in connection with FIGS. 2A through 2D, such as implantation processing, annealing, etc. can be applied to FIGS. 3A through 3C.

As shown in FIG. 3A, a gate dielectric 320 is disposed between a substrate portion 360 and a gate electrode 310. FIG. 3A illustrates the MOSFET device 300 after the gate electrode 310 has been etched using a wet etch, a reactive ion etch, and/or so forth. In some embodiments, the gate dielectric 320 can be an oxide that is thermally grown and/or deposited. In some embodiments, the gate electrode 310 can be a polysilicon gate electrode that is deposited on the gate dielectric 320, and etched to form the shape shown in FIG. 3A. In some embodiments, the substrate portion 360 shown in FIG. 3A can be, for example, doped with a P-type dopant and can be a P-well region of the MOSFET device 300. In some embodiments, the substrate portion 360 can be, or can be associated with, an epitaxial layer (e.g., an N-type epitaxial layer).

As shown in FIG. 3A, a lightly doped drain region 340 is formed within the substrate portion 360 by driving (e.g., implanting) a dopant through the gate dielectric 320 and into the substrate portion 360. In some embodiments, the doping of the substrate portion 360 to form the lightly doped drain region 340 can be performed using an implant process (e.g., an ion implantation process using an accelerator). In some embodiments, the lightly doped drain region 340 can be doped with an N-type dopant such as phosphorus, boron, arsenic, and/or so forth.

In some embodiments, the lightly doped drain region 340 can be defined using a variety of implantation process parameters such as an angle of implantation, a duration of implantation, a dopant type, an acceleration energy, a dopant dose, and/or so forth. For example, in some embodiments, the dopant of the lighted doped drain region 340 can be implanted vertically, at an angle directed toward, and/or at an angle directed away from the gate electrode 310. For example, the dopant of the lightly doped drain region 340 can be approximately between 0 and 60 degrees (e.g., 10 degrees, 35 degrees, 45 degrees) with respect to a vertical axis that is orthogonal to (or substantially orthogonal to) a surface of the substrate portion 360. In this embodiment, because the dopant(s) of the lightly doped drain region 340 is angled in toward the gate electrode 310, the lightly doped drain region 340 can extend under the gate electrode 310 as shown in FIG. 3A. In some embodiments, the dopant of the lightly doped drain region 340 can extend under the gate electrode 310 due to diffusion of the dopant(s) during or after the implantation process.

As shown in FIG. 3B, a medium doped drain region 330 is formed within the substrate portion 360 (e.g., within the lightly doped drain region 340 within the substrate portion 360) by heating the MOSFET device 100. The heating of the MOSFET device 100 is illustrated with wavy lines. When heating the lightly doped drain region 340 of the substrate portion 360, dopants (e.g., dopant molecules) that are part of the lightly doped drain region 340 can migrate (e.g., diffuse, migrate based on the segregation effect) until the medium doped drain region 330 is formed within the substrate portion 360. The heat to cause the migration can be applied to the MOSFET device 100 during an annealing process. In this embodiment, the annealing process can be performed, at least in part, to improve the quality of (e.g., remove dislocations and/or other defects from) the gate dielectric 320. In some embodiments, the heat applied to the MOSFET device 100 to form the medium doped drain region 330 can be associated with a relatively slow oxidation process (e.g., a gate seal oxidation process). In some embodiments, the heat can be applied in addition to chemicals (e.g., inert gases, water vapor), pressure (or negative pressure), and/or so forth.

Rather than performing an annealing process (and applying heat) before the lightly doped drain region 340 is formed (e.g., implanted) within the substrate portion 360 (as described in connection with FIGS. 2A through 2D), the annealing process, in this embodiment, is performed after the lightly doped drain region 340 is formed within the substrate portion 360 so that heat applied to the MOSFET device 100 during the annealing process can cause segregation and the formation of the medium doped drain region 330. In some embodiments, the annealing process can be a relatively slow annealing process (e.g., can have a relatively long duration) between a few minutes and several hours (e.g., 2 to 4 hours), and at one or more temperatures (or temperature profiles) (e.g., 700° C., 800° C., 950° C., 1150° C.). In some embodiments, a first annealing process can be performed before the lightly doped drain region 340 is formed (e.g., implanted) within the substrate portion 360, and a second annealing process can be performed after the lightly doped drain region 340 is formed so that the medium doped drain region 330 can be formed from the dopants (relying on the segregation effect) to form the lightly doped drain region 340.

Although not shown in connection with FIGS. 3A through 3C, in some embodiments, an additional implantation process can be performed to form at least a portion of the medium doped drain region 330. In some embodiments, the additional implantation process can be performed after the medium doped drain region 330 has been at least partially formed using heat. For example, after the medium doped drain region 330 has been at least partially formed from the lightly doped drain region 340 by applying heat to the MOSFET device 100 during an annealing process (e.g., an annealing process that is part of an oxidation process), formation of the medium doped drain region 330 can be completed using an implantation process. In such embodiments, additional dopants to form (or complete formation of) the medium doped drain region 330 can be implanted. In such embodiments, the implantation process to further form the medium doped drain region 330 can be performed using different implantation process parameters (e.g., angle of implantation, duration of implantation, dopant type, acceleration energy, dopant dose, and/or so forth) than implantation process parameters used to form (e.g., originally form) the lightly doped drain region 340.

In some embodiments, the additional implantation process can be performed before the medium doped drain region 330 has been at least partially formed using heat. For example, after the lightly doped drain region 340 has been formed using a first implantation process, the medium doped drain region 330 can be at least partially formed using a second implantation process. The medium doped drain region 330 can be further formed by applying heat to the MOSFET device 100 (and causing diffusion of dopants from the lightly doped drain region 340 into the medium doped drain region 330) during an annealing process (based on a segregation effect).

FIG. 3C is a diagram that illustrates a spacer 312 disposed lateral to the gate electrode 310. The spacer 312 is described as being lateral to the gate electrode 310 because the spacer 312 is disposed to the left (or right) of (in a horizontal direction to) the gate electrode 310 when the substrate portion 360 is oriented as shown in FIG. 3C. In this embodiment, the spacer 312 is in contact with the gate electrode 310. Also, at least a portion of the spacer 312 is disposed lateral to the gate dielectric 320. In some embodiments, the spacer 312 can be made of, for example, a tetraethyl orthosilicate (TEOS) material.

Also, as shown in FIG. 3C, a heavily doped drain region 350 is formed after the spacer 312 has been formed. In some embodiments, the heavily doped drain region 350 can be formed using an implantation process. The heavily doped drain region 350 can have a dopant concentration (e.g., a dopant level) that is greater than a dopant concentration of the medium doped drain region 330 and/or that is greater than a dopant concentration of the lightly doped drain region 340. In some embodiments, an angle of implantation, a duration of implantation, a dopant type, an acceleration energy and/or so forth of the heavily doped drain region 350 can be the same as, or different from that of implantation of the medium doped drain region 330 and/or the lightly doped drain region 340.

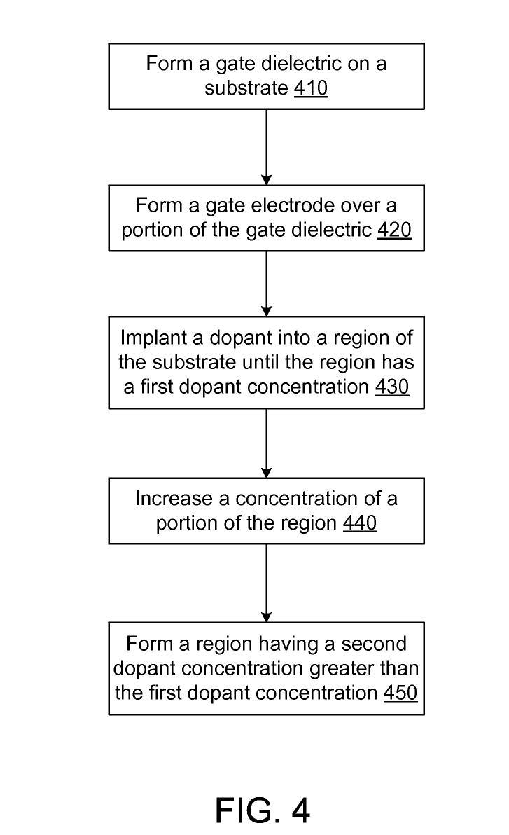

FIG. 4 is a flowchart that illustrates a method for forming a medium doped drain region, according to an embodiment. As shown in FIG. 4, a gate dielectric is formed on a substrate (block 410). In some embodiments, the gate dielectric can be similar to, for example, the gate dielectric 220 shown in FIG. 2A. In some embodiments, the gate dielectric can be an oxide formed on the substrate using an oxidation process (e.g., a thermal oxidation process, a deposited oxidation process).

After the gate dielectric has been formed, a gate electrode is formed over a portion of the gate dielectric (block 420). In some embodiments, the gate electrode can be similar to, for example, the gate electrode 210 shown in FIG. 2A. In some embodiments, the gate electrode can be a polysilicon gate electrode. In some embodiments, polysilicon deposited over the gate dielectric can be etched using an etching process (e.g., a wet etch process, a reactive ion etching process) to form the gate electrode.

A dopant is implanted into a region of the substrate until the region has a first dopant concentration (block 430). In some embodiments, the region having the first dopant concentration can be similar to, for example, the lightly doped drain region 240 shown in FIG. 2B. In some embodiments, the region having the first concentration can be formed using an implantation process having a variety of implantation process parameters such as an angle of implantation, a duration of implantation, a dopant type, an acceleration energy, a dopant dose, and/or so forth.

As shown in FIG. 4, a concentration of a portion of the region is increased (block 440). In some embodiments, the portion of the region can be similar to, for example, the medium doped drain region 230 shown in FIG. 2C and/or the medium doped drain region 330 shown in FIG. 3B.

In some embodiments, the concentration of the portion of the region can be increased by applying heat that causes migration of dopants (based on a segregation effect) from other parts of the region (outside of the portion of the region) into the portion of the region. In some embodiments, the concentration of the portion of the region can be increased by further doping the portion of the region during the implantation process, or using a separate implantation process (e.g., an implantation process separate from the implantation process used form the region having the first concentration). In some embodiments, the implantation process used to increase the concentration of the portion of the region can have implantation process parameters (e.g., angle of implantation, duration of implantation, dopant type, acceleration energy, dopant dose) that are different than implantation process parameters used to form the region having the first dopant concentration.

A region having a second dopant concentration greater than the first dopant concentration is formed (block 450). In some embodiments, the region having the second dopant concentration can be a heavily doped drain region. In some embodiments, the second dopant concentration can be greater than the concentration of the portion of the region that has been increased. In some embodiments, the concentration of the portion of the region can be between the first dopant concentration and the second dopant concentration.

While the various embodiments described above can be implemented in silicon, these embodiments can also be implemented in silicon carbide, gallium arsenide, gallium nitride, diamond, and/or so forth. Further, the cross-sectional views of the different embodiments may not be to scale, and as such are not intended to limit the possible variations in the layout design of the corresponding structures. In some embodiments, one or more types of semiconductor substrates can be used to produce the MOSFET devices. Some examples of substrates that can be used include, but are not limited to, silicon wafers, epitaxial Si layers, bonded wafers such as used in silicon-on-insulator (SOI) technologies, and/or amorphous silicon layers, all of which may be doped or undoped.

Implementations of the various techniques described herein may be implemented in digital electronic circuitry, or in computer hardware, firmware, software, or in combinations of them. Some implementations may be implemented using various semiconductor processing and/or packaging techniques.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

1. An apparatus, comprising:
a substrate;
a gate electrode;
a gate dielectric having at least a portion disposed between the gate electrode and the substrate;
a heavily doped drain region disposed within the substrate;
a lightly doped drain region within the substrate and in contact with the heavily doped drain region; and
a medium doped drain region disposed within the lightly doped drain region and having a dopant concentration between a dopant concentration of the heavily doped drain region and a dopant concentration of the lightly doped drain region.

2. The apparatus of claim 1, wherein the dopant concentration of the medium doped drain region is greater than 1.5 times the dopant concentration of the lightly doped drain region.

3. The apparatus of claim 1, wherein the dopant concentration of the medium doped region is greater than three times the dopant concentration of the lightly doped drain region.

4. The apparatus of claim 1, wherein the lightly doped drain region and the medium doped drain region are disposed substantially lateral to and are in contact with the heavily doped drain region.

5. The apparatus of claim 1, wherein the medium doped drain and the heavily doped drain define a first interface, the lightly doped drain and the heavily doped drain region define a second interface, the first interface is disposed between the gate dielectric and the second interface.

6. The apparatus of claim 1, wherein the medium doped drain region has a volume smaller than a volume of the lightly doped drain region, the heavily doped drain region has a volume greater than the volume of the medium doped drain region.

7. The apparatus of claim 1, wherein the medium doped drain region is doped with an N-type dopant.

8. The apparatus of claim 1, wherein the medium doped drain region has a length along a surface of the substrate that is greater than a length of the lightly doped drain region along the surface of the substrate and disposed below the gate dielectric.

9. The apparatus of claim 1, further comprising:
a spacer disposed over at least a portion of the lightly doped drain region, at least a portion of the medium doped drain region, and at least a portion of the heavily doped drain region.

10. An apparatus, comprising:
a substrate;
a gate electrode;
a gate dielectric having at least a first portion disposed between the gate electrode and the substrate;
a spacer disposed over a second portion of the gate dielectric and in contact with the gate electrode;
a first doped drain region at an interface between gate dielectric and the substrate; and
a second doped drain region at an interface between the second portion of the gate dielectric and the substrate, the second doped drain region having a dopant concentration configured to offset electric charge associated with a plurality of electrons trapped at the interface between the second portion of the gate dielectric and the substrate in response to hot carrier injection, the dopant concentration of the second doped drain region being greater than a dopant concentration of the first doped drain region.

11. The apparatus of claim 10, further comprising:
a third doped drain region disposed within the substrate, the second doped drain region being disposed between the first doped drain region and the third doped drain region, the dopant concentration of the second doped drain region being less than a dopant concentration of the third doped drain region.

12. The apparatus of claim 10, wherein the dopant concentration of the second doped region is greater than 1.5 times the dopant concentration of the first doped drain region.

13. The apparatus of claim 10, wherein the first doped drain region defines a perimeter on a surface of the substrate that is outside of at least a portion of a perimeter of the second doped region at the surface of the substrate.

14.-20. (canceled)

21. An apparatus, comprising:
a gate dielectric disposed on a substrate;
a gate electrode disposed over a portion of the gate dielectric;
a dopant implanted in a region of the substrate until a first portion of the region has a first dopant concentration, the region having a second portion that is increased in concentration to a concentration greater than the first dopant concentration; and
a drain region having a second dopant concentration greater than the first dopant concentration.

22. The apparatus of claim 21, wherein the dopant is implanted at a first angle into the first portion of the region, the concentration of the second portion of the region is increased through an implant performed at a second angle different from the first angle.

23. The apparatus of claim 21, wherein the concentration of the second portion of the region is increased using an annealing process that increases the concentration of the second portion of the region through a segregation effect.

24. The apparatus of claim 21, wherein the concentration of the second portion of the region is increased until the second portion of the region has a third dopant concentration greater than the first dopant concentration and less than the second dopant concentration.

25. The apparatus of claim 21, wherein the second portion of the region has a volume that is smaller than a volume of the first portion of the region having the first dopant concentration.

26. The apparatus of claim 21, further comprising:
a spacer disposed over the region, at least a portion of the spacer is projected over the first portion of the region having the first concentration.

27. The apparatus of claim 21, further comprising:
a spacer defining a perimeter on a surface of the substrate that is outside of at least a portion of a perimeter of the second portion of the region at the surface of the substrate.
